(19) United States
(12) Patent Application Publication
(10) Pub. No.: US 2019/0140205 A1
(43) Pub. Date: May 9, 2019

(54) LIGHT EMITTING ELECTROCHEMICAL CELL AND METHOD OF MANUFACTURE

(71) Applicant: CPI Innovation Services Limited, Redcar (GB)

(72) Inventors: Alex COLE, Durham (GB); Adam GRAHAM, Durham (GB)

(73) Assignee: CPI Innovation Services Limited, Redcar (GB)

(21) Appl. No.: 16/307,337

(22) PCT Filed: Jun. 8, 2017
(86) PCT No.: PCT/GB2017/051668

§ 371 Date: Dec. 5, 2018

(30) Foreign Application Priority Data
Jun. 9, 2016 (GB) 1610075.2

(51) Int. Cl. H01L 51/50; H01L 51/52; H01L 51/00; H01L 51/56

(52) U.S. Cl. CPC H01L 51/5032; H01L 51/5206; H01L 51/5221; H01L 51/0003; H01L 2251/308; H01L 51/0022; H01L 51/56; H01L 51/0037; H01L 51/0043; H01L 51/0026

(57) ABSTRACT

A light emitting electrochemical cell (LEEC, 21) is described comprising a first electrode (23); a further electrode (26) comprising ionic salt; and a light emitting element (25) between the first (23) and further electrodes (26). A method of manufacturing a light emitting electrochemical cell (LEEC, 21) is described comprising: forming a first electrode (23); forming a light emitting element (25) overlying the first electrode (23); forming a further electrode (26) by applying a substance comprising ionic salt to a side of the light emitting element (25) furthest from the first electrode (23).

The present invention relates to a light emitting electrochemical cell (LEEC) and method of manufacturing an LEEC. In particular, but not exclusively, the present invention relates to an LEEC including ionic salts.

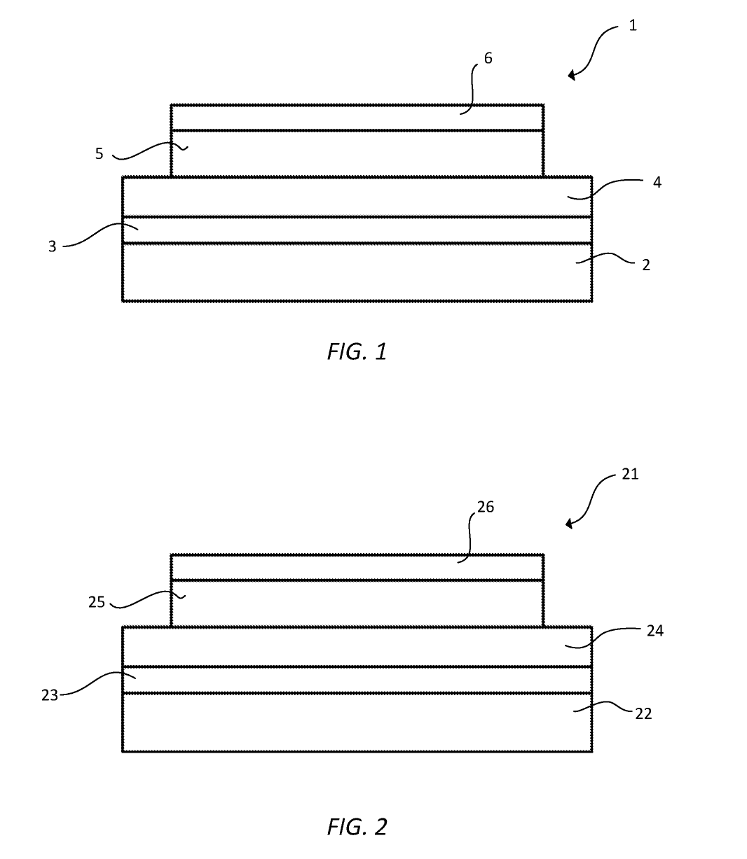

A light emitting electrochemical cell (LEEC) typically includes of a number of layers deposited onto a substrate. FIG. 1 illustrates a known device 1 including a substrate 2 with an indium tin oxide (ITO) layer 3 deposited on one side of the substrate. The substrate 2 may be formed from glass, or for flexible LEECs, it may be formed from a flexible polymer such as PET. A PEDOT:PSS layer 4 is coated on top of the ITO layer 3. The PEDOT:PSS layer 4 acts as a planerising layer and a buffer, and may also provide a work function assisting with hole injection. A light emitting layer 5 is deposited on top of the PEDOT:PSS layer 4. The light emitting layer 5 is typically formed from an electroluminescent material such as Poly(1,4-phenylene vinylene) (PPV) or its soluble derivatives, Poly[2-methoxy-5-(2-ethylhexyloxy)-1,4-phenylenevinylene] (MEH-PPV), Poly(1,4-phenylene) (PPP) or its various derivatives, Polyfluorenes (PFO), Poly(thiophenes) or their derivatives, Nitrogen-Containing Polymers such as Poly(2,5-pyridinevinylene), inorganic transition metal complexes such as those containing Iridium complexes, for example, hetroleptic bis-cyclometalated iridium(III) complexes, for example Tris[2-phenylpyridinato-C2,N]iridium(III). Specific materials used include Merck SuperYellow which is a PPV derivative or Merck SPG01T which is a poly bis spiro fluorene. Additionally the light emitting layer may include an ionic salt. The ionic salt may include any of MATs (Methyl-trioctylammonium trifluoromethanesulfonate), OTf (trifluoromethanesulfonate), TEA/OTf (Tetraethylammonium trifluoromethanesulfonate), K/OTf (Potassium trifluoromethanesulfonate), NH4/OTf (ammonium trifluoromethanesulfonate), Li/OTf (Lithium trifluoromethanesulfonate), EMIM/PF6 (1-Ethyl-3-methylimidazolium hexafluorophosphate), BMP/IMIDE (1-Butyl-1-methylpyrrolidinium bis(trifluoromethylsulfonyl)imide), TBA/PF6 (Tetrabutylammonium hexafluorophosphate), EMIM/OTf (1-Ethyl-3-methylimidazolium trifluoromethanesulfonate), or any combination thereof or any other suitable ionic salt.

A cathode layer 6 is formed on top of the light emitting layer 5, typically by thermal evaporation of aluminium. LEECs, for example as shown in FIG. 1, are usually made by sequentially depositing each of the layers onto the substrate 1. This can be by evaporation or by spin coating, for example. However, this process is generally very time-consuming and so an alternative manufacturing method is desirable that can reduce production times. In addition, the existing methods can be expensive since spin coating can lead to higher material wastage, and the evaporated layers require a vacuum and expensive tools (e.g. vacuum chambers).

Roll-to-roll manufacture of LEECs has previously been proposed. However, the current methods of depositing the ITO layer and the cathode layer using evaporation are also time consuming as well as expensive in a roll-to-roll process.

The present invention seeks to at least partly mitigate the above-mentioned problems.

According to a first aspect of the present invention there is provided a light emitting electrochemical cell (LEEC), comprising:
a first electrode
a further electrode comprising ionic salt; and
a light emitting element between the first and further electrodes.

According to a second aspect of the present invention there is provided a method of manufacturing a light emitting electrochemical cell (LEEC), comprising:
forming a first electrode;
forming a light emitting element overlying the first electrode;
forming a further electrode by applying a substance comprising ionic salt to a side of the light emitting element furthest from the first electrode.

The further electrode forms the cathode layer in the light emitting electrochemical cell (LEEC).

According to a third aspect of the present invention there is provided a conductive substance comprising ionic salt solution and in some examples ionic liquid solution for forming a cathode layer in a light emitting electrochemical cell (LEEC).

According to a fourth aspect of the present invention there is provided a use of a conductive substance comprising ionic salt solution and in some examples ionic liquid solution for forming a cathode layer in a light emitting electrochemical cell (LEEC).

The ionic salt in the further electrode forming the cathode layer improves conductivity of the cathode layer in the z-plane of the device (perpendicular to the plane of the cathode layer).

In a preferred embodiment the further electrode forming the cathode layer additionally comprises conductive particles. Conductive particles in the further electrode layer may tend to align in the x-y plane during the fabrication process giving good x-y plane conductivity but leaving gaps in the z-plane.

The presence of ionic salts in the further electrode forming the cathode layer then helps to improve the z-plane conduction of electrons from the cathode layer into the light emitting region defined by the light emitting element. This migration out of the light emitting region altogether is a characteristic feature of the operation of an LEEC in accordance with the principles of the invention.

Certain embodiments of the invention provide the advantage that an LEEC can be manufactured more efficiently using a roll-to-roll process, compared to known methods. In particular certain embodiments of the invention provide the advantage that the further electrode forming the cathode layer of the LEEC can be manufactured more efficiently using a roll-to-roll process, compared to known methods such as evaporation, for example of aluminium.

Certain embodiments of the invention provide the advantage that the further electrode forming the cathode layer can be screen printed.

Certain embodiments of the invention provide the advantage that an LEEC can be produced having improved lifetime compared to known devices.

Certain embodiments of the invention provide the advantage that a cathode layer can be screen printed without compromising on efficiency, output, or stability of the LEEC.

Embodiments of the invention are further described hereinafter with reference to the accompanying drawings, in which:

FIG. 1 illustrates a known LEEC structure; and

FIG. 2 illustrates an example LEEC structure according to an embodiment of the invention.

In the drawings like reference numerals refer to like parts.

FIG. 2 illustrates an LEEC 21 according to a specific embodiment. The LEEC 21 includes a substrate 22, which in this example is glass. The substrate is coated with an ITO layer 23, which forms a first electrode.

A PEDOT:PSS layer 24 lies on top of the ITO layer. The PEDOT:PSS layer 24 is an optional layer that acts as a planerising layer and a buffer to help improve performance of the LEEC.

There is a light emitting element on top of the PEDOT:PSS layer, which forms a light emitting layer 25. The light emitting layer 25 in this example includes a light emitting polymer and may also include an ionic salt.

On top of the light emitting layer 25, there is a further electrode 26 (cathode). Aptly, the further electrode is directly adjacent the light emitting layer. The further electrode 26 includes an ionic salt.

As used herein, the term ‘ionic salt’ is used to refer to any ionic salt or class of ionic salt including ionic liquids. The term ‘ionic salt’ is not limited to solid compositions and can also include ionic salts in liquid form (i.e. ionic liquids). The term ‘ionic liquid’ refers specifically to a sub class of ionic salt in which the ions are poorly coordinated, resulting in them being liquid below 100° C.

The ionic salt is provided as an ionic salt solution and includes from 50 to 1000 mg of ionic salt per 1 ml of solvent. Aptly, the ionic salt solution includes from 50 to 500 mg of ionic salt per 1 ml of solvent. More aptly the ionic salt solution includes from 100 to 250 mg of ionic salt per 1 ml of solvent.

In this example, the ionic salt solution includes 400 mg of ionic salt per 1 ml of solvent. The solvent may be any suitable solvent. In this example the solvent is toluene (methylbenzene).

The further electrode also includes conductive particles. In this example the further electrode 26 includes silver particles.

The LEEC 21 may be manufactured by first forming the first electrode. The first electrode may be formed by evaporating the ITO layer 23 onto the substrate 22.

A PEDOT:PSS layer 24 (if required) is coated onto the first electrode, adjacent the ITO layer 23 by spin coating.

The light emitting layer 25 is then deposited onto the first electrode (or optional PEDOT:PSS layer 24), through spin coating or printing. The light emitting layer 25 can then be baked to dry, usually above 80° C. for around 5 to 20 minutes. For example, the light emitting layer 25 may be baked to dry at between 80° C. and 120° C. for around 10 minutes.

A substance including ionic salt is then applied to a side of the light emitting layer furthest from the first electrode to form the further electrode 26. This may be applied by screen printing the substance onto the light emitting layer 25.

As an alternative to the example described above, a flexible substrate 22 may be used. This allows the LEEC to be manufactured using a roll to roll process. The flexible substrate may be formed from PET (Polyethylene terephthalate), PP (Polypropylene), PCTFE (Polycholrotrifluoroethene), PEN (Polyethylene naphthalate), PC (Polycarbonate), PI (Polyimide), PA (Polyamide), or flexible glass (such as ‘Willow® Glass’ from Corning, for example.

In a first step of the roll to roll manufacturing process, a flexible substrate is chosen. This may be, for example, a heat stabilised PET.

An ITO layer (forming a first electrode comprising the anode layer of the fabricated LEEC) is then deposited by sputtering onto the flexible substrate to form an ITO coated substrate roll. This process is carried out in a roll to roll sputtering machine. The ITO layer may be deposited in a pattern (e.g. of parallel lines) by using a sacrificial shadow mask layer. This pattern helps with separating the roll into individual LEEC devices once all the layers have been formed.

The ITO coated substrate roll is then loaded into a roll to roll printing tool.

Using a first slot die, a striped pattern of PEDOT:PSS is deposited onto the ITO coated substrate roll. This is then dried in a forced air convention oven at around 120 to 130° C. for around 0.5 to 20 minutes.

The roll then passes through a second slot die where a solution including a light emitting material (an LEEC solution) is deposited in a striped pattern. The striped pattern may include stripes of LEEC solution 16 mm wide and spaced apart by 10 mm. This forms the light emitting layer of the LEECs. The roll is then dried in a forced air convection oven at about 120 to 130° C.

The roll then passes through a rotary screen print system. The rotary screen print system prints onto the roll an ink including conductive particles and ionic salt solution. This printed layer forms the further electrode (cathode) layer. A slot die can optionally be used to print the cathode layer in a striped pattern.

The further electrode layer is then UV cured, and/or thermally dried at around 120 to 130° C. in a forced air convention oven.

The roll is then wound and transferred onto a second roll to roll manufacturing tool. The second roll to roll tool is an encapsulation tool, which is inertised with nitrogen. The roll is sealed in the encapsulation tool, which expels air and replaces it with high purity nitrogen gas. This gas is recirculated through a tool that ensures the levels of water and oxygen molecules are each less than 5 ppm (5 parts per million). This is important because oxygen and water can cause device failure during operation. The water vapour penetration rate should be less than 10⁻⁴ g/m²/day otherwise the device will degrade over time.

The roll is further dried through a forced air nitrogen oven at around 120° C. This further drying step helps to completely dry the PEDOT:PSS, light emitting and cathode layers and ensure they are free from oxygen.

A flexible barrier film that is impermeable to water and oxygen is then laminated onto both sides of the roll, using a dry pressure sensitive adhesive, to encapsulate the layers. This protects the LEEC from water and oxygen, which can cause failure of the LEEC.

The roll is then separated into individual LEEC devices with suitable cutting apparatus, for example a laser, knife, blade, or scissors. Connections to the first electrode (anode) and the cathode layers are then made using crimp connectors.

Where the anode and cathode layers cross, provided there is a light emitting layer in between, the device will emit light when connected to a suitable power supply. In the portions where there is no light emitting layer in between the cathode and anode (i.e. due to the separation of the striped pattern of the light emitting layer), there will be no light emitted.

Various modifications to the detailed designs as described above are possible. For example, many different compositions including ionic salt may be suitable for the forming the cathode layer.

The ionic salt may include an ionic liquid. For example, the ionic liquid may include any of MATs (Methyl-trioctylammonium trifluoromethanesulfonate), OTf (trifluoromethanesulfonate), TEA/OTf (Tetraethylammonium trifluoromethanesulfonate), K/OTf (Potassium trifluoromethanesulfonate), NH4/OTf (ammonium trifluoromethanesulfonate), Li/OTf (Lithium trifluoromethanesulfonate), EMIM/PF6 (1-Ethyl-3-methylimidazolium hexafluorophosphate), BMP/IMIDE (1-Butyl-1-methylpyrrolidinium bis(trifluoromethylsulfonyl)imide), TBA/PF6 (Tetrabutylammonium hexafluorophosphate), EMIM/OTf (1-Ethyl-3-methylimidazolium trifluoromethanesulfonate), or any combination thereof.

The ionic salt may be provided in an ionic salt solution including ionic salt and solvent. The solvent may be any suitable solvent, for example, toluene (methylbenzene), acetone, xylene, isopropyl alcohol, or tetrahydrofuran.

The ionic salt solution may include from around 100 to 1000 mg of ionic salt per 1 ml of solvent. Aptly, the ionic salt solution includes 400 mg of ionic salt per 1 ml of solvent.

The cathode may be screen printed using a conductive paste including the ionic salt or ionic salt solution. Aptly, the paste is a screen printable paste.

To form the screen printable paste, ionic salt may be blended directly into the conductive paste. Alternatively, the ionic salt may be provided as an ionic salt solution, which may be mixed with the conductive paste.

The screen printable paste may include conductive particles. The conductive particles may for example include, metallic particles, silver particles, carbon particles, graphene, silver nanowires, or any combination thereof.

The conductive paste may include from 0.5 to 4 ml of ionic salt solution per 10 ml of conductive paste. Aptly, the conductive paste may include from 1 to 2 ml of ionic salt solution per 10 ml of conductive paste.

Rather than using a substrate coated with ITO, the first electrode (anode) may be of any suitable form known in the art. For example, the substrate may be a glass substrate (where roll to roll manufacture is not required). Alternatively, where roll to roll manufacture is required or where it is desirable to have a flexible LEEC device, the substrate may be a flexible substrate. The flexible substrate may be formed from a polymer material. Suitable polymers may include PET (Polyethylene terephthalate), PP (Polypropylene), PCTFE (Polycholrotrifluoroethene), PEN (Polyethylene naphthalate), PC (Polycarbonate), PI (Polyimide), PA (Polyamide), or flexible glass (such as ‘Willow® Glass’ from Corning.

Rather than using an ITO coating on the substrate, other materials may be used. For example the substrate may be coated with carbon nanowires, graphene, metal grid, Al or F doped ZnO (AZO or FZO), other transparent conducting oxides, PEDOT or other transparent conducting polymers.

The light emitting layer (LEEC solution) may include any suitable light emitting polymer and may also include any suitable ionic salt. The light emitting element may additionally or alternatively include any of an ionic transition metal complex (ITMC), or a small molecule phosphorescent system. Additionally, the light emitting layer may include an ionic salt. The ionic salt is mixed with the LEEC solution before depositing the light emitting layer.

With the above described embodiments, the ionic salt in the cathode layer enables the cathode layer to be screen printed and therefore enables roll to roll manufacture of LEEC devices.

The ionic salt in the cathode layer improves conductivity of the cathode layer in the z-plane of the device (perpendicular to the plane of the cathode layer). Conductive particles in the cathode layer tend to align in the x-y plane during the printing process giving good x-y plane conductivity but leaving gaps in the z-plane. The presence of ionic salts in the cathode layer helps to improve both the z-plane conduction of electrons from the cathode layer into the light emitting layer, and of holes out of the light emitting layer into the cathode layer.

The ionic salts also help the light emitting layer to continue to function normally when a screen printed cathode layer is used. As illustrated in the examples below, without the presence of ionic salt in the screen printable cathode layer, the LEEC device emits very dim light compared to a standard LEEC with an aluminium cathode, even at voltages much higher than normally required. In the examples where the ionic salt is present in the screen printed cathode layer, the device emits a brighter light and has a longer lifetime and is comparable to a standard LEEC having an aluminium cathode.

Although the manufacturing method described above is a roll to roll manufacturing method, it will be appreciated that the LEEC may be manufactured by other suitable methods, for example flatbed screen printing, doctor blading or sheet to sheet systems.

### EXAMPLES

To test the efficiency of different cathode layers, a standard LEEC device structure was used for each sample. This was a 4 inch (10.16 cm) square glass substrate with an ITO coating. The ITO layer was patterned using an etching process to give six 10 mm parallel lines, each 10 mm apart. A PEDOT:PSS layer was then spin coated onto the patterned ITO layer to act as both a planerising layer and a buffer. A yellow polymer LEC solution was then spin coated onto the device to form a light emitting layer and the device was baked to dry. A range of different coloured LEC solutions can be used. In this example, the LEC solution includes a 50 parts light emitting polymer to 1 part ionic salt in a host solvent (toluene).

A cathode layer was added to the device in a 10 mm striped pattern orthogonal to the stripes of the ITO layer, thus creating 16 10 mm square individual devices. Each one of these devices was then encapsulated with glass and epoxy glue.

A control sample having a cathode layer formed from evaporated aluminium was prepared. All other devices had a screen printed silver ink based cathode layer deposited onto the light emitting layer.

Five different silver ink based (silver paste) solutions were prepared using commercially available screen printable conductive silver paste as a base material. This was a paste including a dispersion of silver particles within a solution of polymer binder and VOC (volatile organic compound) solvents.

A solution of toluene (methylbenzene), with ionic salt dissolved in at a concentration of 100 mg of ionic salt per 1 ml of toluene was also prepared. This is referred to below as ionic toluene solution.

LEEC samples were prepared having cathode layers formed from the following silver paste compositions;
1. 10 ml (22.7 g) silver paste
2. 10 ml (22.7 g) silver paste, 1 ml (100 mg) of ionic toluene solution
3. 10 ml (22.7 g) silver paste, 2 ml (200 mg) of ionic toluene solution
4. 10 ml (22.7 g) silver paste, 1 ml toluene
5. 10 ml (22.7 g) silver paste, 2 ml toluene

Each sample (including the aluminium control sample), was tested for luminosity, current and voltage characteristics.

The control sample aluminium cathode device lit (as expected) at 8 V and was reduced to 5 V after 1 hour, emitting a steady 50 cd/m².

Samples having cathode layers 1, 4 and 5 did not light at 8 V. These samples only emitted very dim (up to 4 cd/m²) light after increasing the voltage to 20 V. However, all of these samples failed due to an electrical shortage after only 2 to 3 minutes—thereby destroying the samples.

The sample having cathode layer 2 lit at 8 V and was reduced to 5 V after 1 hour. At this point it was emitting light at 20 cd/m².

The sample having cathode layer 3 lit at 8 V and was reduced to 5 V after 1 hour. At this point it was emitting light at 40 cd/m². Samples having this cathode layer continued to emit light at a constant output for 2 months or even greater. This is comparable to the results given by the control sample with the aluminium electrode.

As such, the samples having a cathode layer containing ionic toluene solution performed much better than the standard screen print silver paste, and were much more stable devices.

It will be clear to a person skilled in the art that features described in relation to any of the embodiments described above can be applicable interchangeably between the different embodiments. The embodiments described above are examples to illustrate various features of the invention.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. A light emitting electrochemical cell (LEEC) comprising:
a first electrode;
a further electrode comprising ionic salt; and
a light emitting element between the first and further electrodes.

2. The LEEC as claimed in claim 1, wherein the ionic salt comprises an ionic liquid.

3. The LEEC as claimed in claim 1, wherein the further electrode is directly adjacent to the light emitting element.

4. The LEEC as claimed in claim 1, wherein the further electrode comprises conductive particles.

5. The LEEC as claimed in claim 4, wherein the conductive particles comprise at least one of metallic particles, silver particles, carbon particles, graphene, and silver nanowires.

6. The LEEC as claimed in claim 1, wherein the first electrode comprises indium tin oxide (ITO) and is coated on a substrate.

7. The LEEC as claimed in claim 1, wherein the light emitting element comprises a light emitting polymer.

8. The LEEC as claimed in claim 1, wherein the light emitting element comprises an ionic transition metal complex (iTMC).

9. The LEEC as claimed in claim 1, wherein the light emitting element comprises a small molecule phosphorescent system.

10. The LEEC as claimed in claim 7, wherein the light emitting element further comprises an ionic salt.

11. The LEEC as claimed in claim 10, wherein the ionic salt comprises an ionic liquid.

12. A method of manufacturing a light emitting electrochemical cell (LEEC), the method comprising:
forming a first electrode;
forming a light emitting element overlying the first electrode; and
forming a further electrode by applying a substance comprising ionic salt to a side of the light emitting element furthest from the first electrode.

13. The method of manufacturing an LEEC as claimed in claim 12, wherein the further electrode is formed by screen printing the substance onto the light emitting element.

14. The method of manufacturing an LEEC as claimed in claim 12, wherein the ionic salt comprises an ionic liquid.

15. The method of manufacturing an LEEC as claimed in claim 12, wherein the ionic salt is provided in an ionic salt solution.

16. The method of manufacturing an LEEC as claimed in claim 15, wherein the ionic salt solution comprises from 50 to 1000 mg of ionic salt per 1 ml of solvent.

17. The method of manufacturing an LEEC as claimed in claim 15, wherein the ionic salt solution comprises 100 mg of ionic salt per 1 ml of solvent.

18. The method of manufacturing an LEEC as claimed in claim 12, wherein the solvent of the ionic salt solution comprises one of toluene/methylbenzene, acetone, xylene, isopropyl alcohol, and tetrahydrofuran.

19. The method of manufacturing an LEEC as claimed in claim 12, wherein the substance comprises a conductive paste.

20. The method of manufacturing an LEEC as claimed in claim 19, wherein the conductive paste comprises conductive particles.

21. The method of manufacturing an LEEC as claimed in claim 19, wherein the substance comprises from 0.5 to 2 ml of ionic salt solution per 10 ml of conductive paste.

22. The method of manufacturing an LEEC as claimed in claim 19, wherein the substance comprises 1 ml of ionic salt solution per 10 ml of conductive paste.

23. A conductive substance comprising ionic salt solution for forming a cathode layer in a light emitting electrochemical cell (LEEC).

24. (canceled)

25. (canceled)

26. (canceled)
